(19) United States
(12) Patent Application Publication
(10) Pub. No.: US 2015/0214179 A1
(43) Pub. Date: Jul. 30, 2015

(54) SEMICONDUCTOR DEVICE INCLUDING FLEXIBLE LEADS

(71) Applicant: Infineon Technologies AG, Neubiberg (DE)

(72) Inventors: Tian San Tan, Melaka (MY); Theng Chao Long, Melaka (MY)

(73) Assignee: Infineon Technologies AG, Neubiberg (DE)

(21) Appl. No.: 14/165,645

(22) Filed: Jan. 28, 2014

(51) Int. Cl. H01L 23/00; H01L 23/31; H01L 21/56

(52) U.S. Cl. CPC H01L 24/70; H01L 21/565; H01L 24/64; H01L 24/89; H01L 23/564; H01L 23/3107; H01L 2924/13091; H01L 2924/13055

(57) ABSTRACT

A semiconductor device includes a semiconductor chip including a transistor. A first flexible lead is electrically coupled to a first electrode on a first surface of the semiconductor chip. A second flexible lead is electrically coupled to a second electrode on the first surface of the semiconductor chip. A third flexible lead is electrically coupled to a third electrode on a second surface of the semiconductor chip, the second surface opposite to the first surface.

### BACKGROUND

Power semiconductor devices, such as transistors, are used in a wide variety of applications, such as portable electronic devices (e.g., mobile phones). Power transistors include Insulated Gate Bipolar Transistor (IGBT) semiconductor chips and Metal-Oxide-Semiconductor Field-Effect Transistor (MOSFET) semiconductor chips. The semiconductor chips have varying voltage and current ratings. The semiconductor chips are made from Si, SiC, GaN, GaAs, or other suitable substrates. Electronic devices continue to take on new shapes and sizes that make conventional power semiconductor devices difficult to integrate into the electronic devices.

For these and other reasons, there is a need for the present invention.

### SUMMARY

One embodiment provides a semiconductor device. The semiconductor device includes a semiconductor chip including a transistor. A first flexible lead is electrically coupled to a first electrode on a first surface of the semiconductor chip. A second flexible lead is electrically coupled to a second electrode on the first surface of the semiconductor chip. A third flexible lead is electrically coupled to a third electrode on a second surface of the semiconductor chip, the second surface opposite to the first surface.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A-1B illustrate one embodiment of a semiconductor device.

FIG. 2 illustrates a side view of one embodiment of a semiconductor device.

FIG. 3 illustrates a side view of another embodiment of a semiconductor device.

FIG. 4 illustrates a side view of another embodiment of a semiconductor device.

FIGS. 5A-5C illustrate embodiments of a flexible lead.

FIGS. 6A-6B illustrate embodiments of a semiconductor device coupled to a Printed Circuit Board (PCB).

FIGS. 7A-7B illustrate embodiments of a semiconductor device coupled to a flexible PCB.

FIGS. 8A-8E illustrate one embodiment of a method for fabricating a semiconductor device.

FIGS. 9A-9C illustrate one embodiment of a mold compound arrangement for a semiconductor device.

FIGS. 10A-10C illustrate another embodiment of a mold compound arrangement for a semiconductor device.

FIGS. 11A-11C illustrate another embodiment of a mold compound arrangement for a semiconductor device.

FIGS. 12A-12C illustrate another embodiment of a mold compound arrangement for a semiconductor device.

FIGS. 13A-13C illustrate another embodiment of a mold compound arrangement for a semiconductor device.

FIGS. 14A-14D illustrate embodiments of flexible lead arrangements for a semiconductor device.

FIG. 15 illustrates a side view of one embodiment of a semiconductor device including ferrite coils around the flexible leads.

FIGS. 16A-16B illustrate embodiments of flexible lead arrangements for a semiconductor device including a source sense flexible lead.

### DETAILED DESCRIPTION

In the following Detailed Description, reference is made to the accompanying drawings, which form a part hereof, and in which is shown by way of illustration specific embodiments in which the disclosure may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As used herein, the term “electrically coupled” is not meant to mean that the elements must be directly coupled together and intervening elements may be provided between the “electrically coupled” elements.

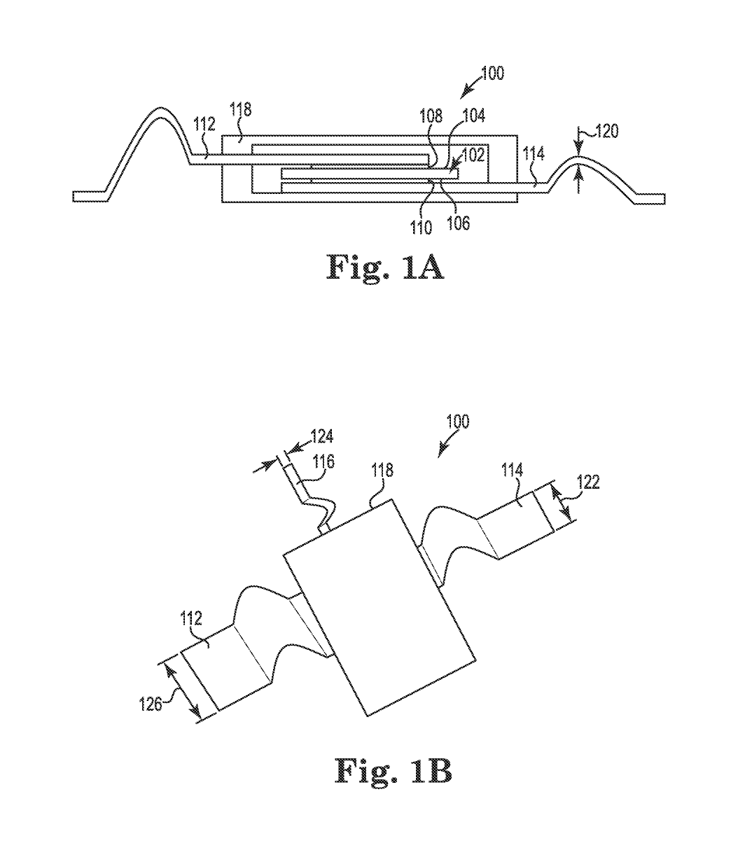

FIG. 1A illustrates a cross-sectional view and FIG. 1B illustrates a top view of one embodiment of a semiconductor device 100. Semiconductor device 100 includes a semiconductor chip 102, flexible leads 112, 114, and 116, and a mold compound 118. A first electrode on a first surface 104 of semiconductor chip 102 is electrically coupled to a first flexible lead 112 through a first solder or sintered joint 108. A second electrode on a second surface 106 opposite to the first surface 104 of semiconductor chip 102 is electrically coupled to a second flexible lead 114 through a second solder or sintered joint 110. A third electrode on either the first surface 104 or the second surface 106 of semiconductor chip 102 is electrically coupled to a third flexible lead 116 through a third solder or sintered joint. Mold compound 118 encapsulates semiconductor chip 102 and portions of flexible leads 112, 114, and 116.

Flexible leads 112, 114, and 116 enable semiconductor device 100 to be mounted onto a conventional flat Printed Circuit Board (PCB) or onto a flexible PCB. In one embodiment, flexible leads 112, 114, and 116 are ribbon leads in which a width 126, 122, and 124 of each lead is greater than a thickness 120 of each lead. In one embodiment, thickness 120 of flexible leads 112, 114, and 116 is between about 0.05 mm and 0.1 mm, width 122 of flexible lead 114 is greater than 2 mm, width 124 of flexible lead 116 is between about 0.7 mm and 1 mm, and width 126 of flexible lead 112 is greater than 2 mm. In other embodiments, the width of each flexible lead is at least ten times greater than the thickness of each flexible lead. In one embodiment, width 126 of flexible lead 112 is greater than width 124 of flexible lead 116, and width 122 of flexible lead 114 is greater than width 126 of flexible lead 112.

Flexible leads 112, 114, and 116 may include copper, lead free alloys, or other suitable materials. In one embodiment, flexible leads 112, 114, and 116 are made of pre-formed copper or another suitable electrically conductive material such that flexible leads 112, 114, and 116 have a spring-like characteristic in which the leads return to their original shape after being pressed, twisted, or stretched. In other embodiments, flexible leads 112, 114, and 116 are made of an elastic or softening material, such as a solder material, that enables the leads to be flexible. For example, flexible lead 112, 114, and 116 may be made of Au—Si, Au—Ge, Au—Sn, Pb—In, Sn—Cu, Sn—Cu—Ni, Sn—Ag, Sn—Ag—Cu, Sn—Ag—Cu—Sb, Sn—Pb, or Bi—Sn.

Semiconductor chip 102 includes a Metal-Oxide-Semiconductor Field-Effect Transistor (MOSFET) or an Insulated Gate Bipolar Transistor (IGBT). In other embodiments, semiconductor chip 102 includes a diode or another suitable component. In one embodiment, first flexible lead 112 is electrically coupled to a source electrode, second flexible lead 114 is electrically coupled to a drain electrode, and third flexible lead 116 is electrically coupled to a gate electrode of a MOSFET semiconductor chip 102. In another embodiment, first flexible lead 112 is electrically coupled to an emitter electrode, second flexible lead 114 is electrically coupled to a collector electrode, and third flexible lead 116 is electrically coupled to a base electrode of an IGBT semiconductor chip 102. Flexible leads 112, 114, and 116 are suitable for high current applications in which the flexible leads may experience high temperatures (e.g., up to 200° C.) due to the high currents.

In one embodiment, each flexible lead 112, 114, and 116 is electrically coupled to semiconductor chip 102 by soft soldering with Sn—Pb, Sn—Ag, Sn—Ag—Cu, or another suitable solder alloy. In another embodiment, each flexible lead 112, 114, and 116 is electrically coupled to semiconductor chip 102 by diffusion soldering with Cu—Sn, Cu—Sn, Sn—Ag, Sn—Ni, or another suitable alloy to provide an intermetallic joint between each flexible lead 112, 114, and 116 and semiconductor chip 102. Each flexible lead 112, 114, and 116 may also be electrically coupled to semiconductor chip 102 by sintering with Au, Ag, Cu, or another suitable metal.

Mold compound 118 includes a hard mold compound or a soft mold compound. For example, the hard mold compound may include epoxy, cross-linked or cross-linkable polymer, plastic, resin, or other electrically insulating material. The soft mold compound may include an elastic or flexible electrically insulating material, such as any gel or elastic like material (e.g., rubber, silicone, gel, or polymer such as Hydro-Carbon, CxHy). In one embodiment, a heat sink is attached to mold compound 118 of semiconductor device 100 to dissipate heat generated by semiconductor chip 102.

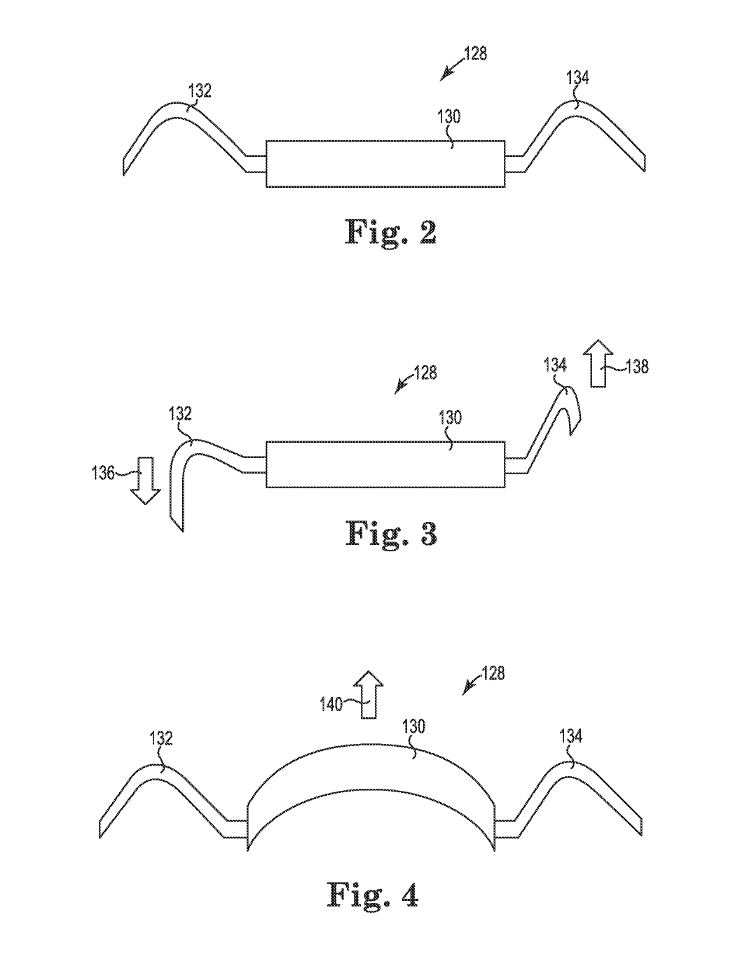

FIG. 2 illustrates a side view of one embodiment of a semiconductor device 128. Semiconductor device 128 includes a mold compound 130 encapsulating a semiconductor chip and pre-formed flexible leads 132 and 134 electrically coupled to the semiconductor chip. In this embodiment, flexible leads 132 and 134 are not flexed and mold compound 130 is not flexed. Accordingly, mold compound 130 may include a hard mold compound in this embodiment.

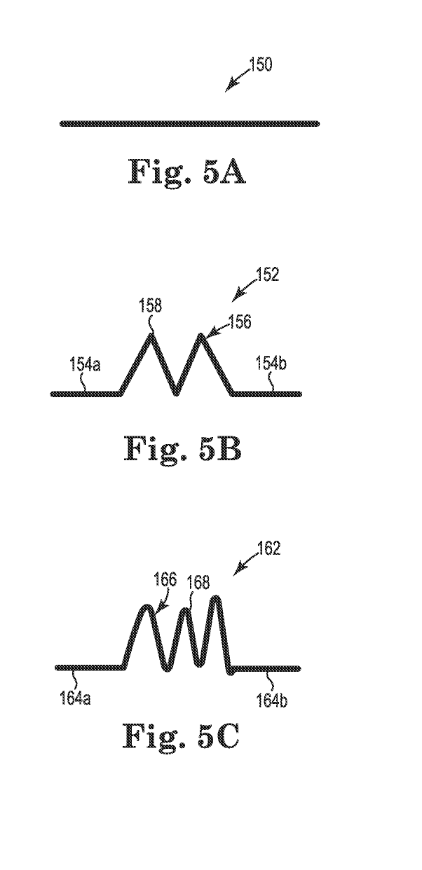

FIG. 3 illustrates a side view of another embodiment of semiconductor device 128. In this embodiment, flexible lead 132 is flexed downward as indicated at 136, and flexible lead 134 is flexed upward as indicated at 138. Flexible leads 132 and 134 are flexed without damaging the leads. Mold compound 130 is not flexed in this embodiment. Accordingly, mold compound 130 may include a hard mold compound in this embodiment.

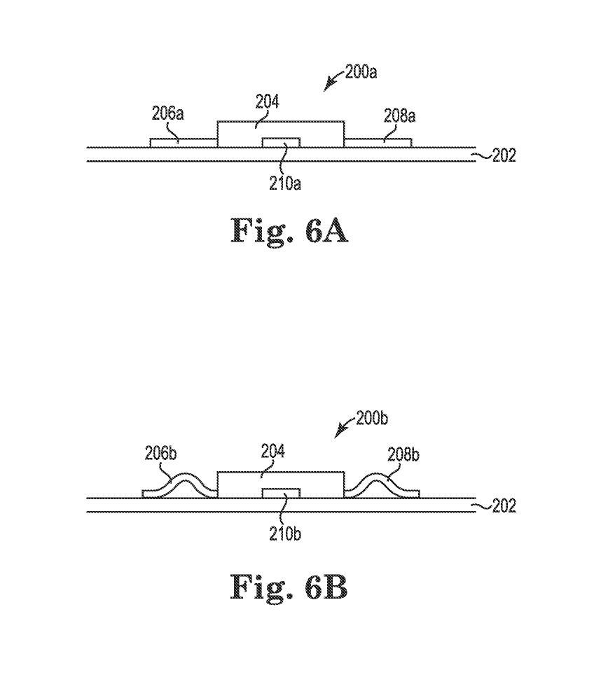

FIG. 4 illustrates a side view of another embodiment of semiconductor device 128. In this embodiment, mold compound 130 is flexed upward as indicated at 140. Mold compound 130 is flexed without damaging the mold compound, the semiconductor chip encapsulated by the mold compound, or flexible leads 132 and 134. Mold compound 130 includes a soft mold compound in this embodiment.

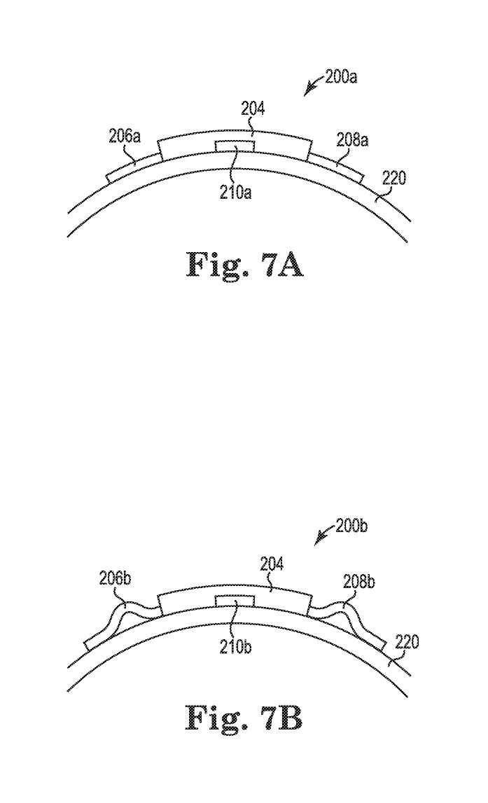

FIG. 5A illustrates a side view of one embodiment of a flexible lead 150. Flexible lead 150 is flat and comprises an elastic or softening material. In one embodiment, flexible lead 150 is used in place of flexible leads 112, 114, and 116 previously described and illustrated with reference to FIGS. 1A and 1B.

FIG. 5B illustrates a side view of another embodiment of a flexible lead 152. Flexible lead 152 includes end portions 154a and 154b and a central portion 156. End portion 154a is flat and is connected to one side of central portion 156, and end portion 154b is flat and is connected to the other side of central portion 156. Central portion 156 is M-shaped and includes a plurality of flat segments connected to each other at points as indicated for example at 158. In this embodiment, central portion 156 includes four segments connected to each other. In other embodiments, however, central portion 156 may include any suitable number of segments connected to each other in a zigzag manner. In one embodiment, flexible lead 152 is used in place of flexible leads 112, 114, and 116 previously described and illustrated with reference to FIGS 1A and 1B.

FIG. 5C illustrates a side view of another embodiment of a flexible lead 162. Flexible lead 162 includes end portions 164a and 164b and a central portion 166. End portion 164a is flat and is connected to one side of central portion 166, and end portion 164b is flat and is connected to the other side of central portion 166. Central portion 166 is serpentine-shaped and includes a plurality of segments connected to each other at curved regions as indicated for example at 168. In this embodiment, central portion 166 includes six segments connected to each other. In other embodiments, however, central portion 166 may include any suitable number of segments connected to each other in a serpentine manner. In one embodiment, flexible lead 162 is used in place of flexible leads 112, 114, and 116 previously described and illustrated with reference to FIGS. 1A and 1B.

While FIGS. 5A-5C illustrate three embodiments of flexible leads having different shapes, the flexible leads may have any suitable shape that enables the leads to be flexible.

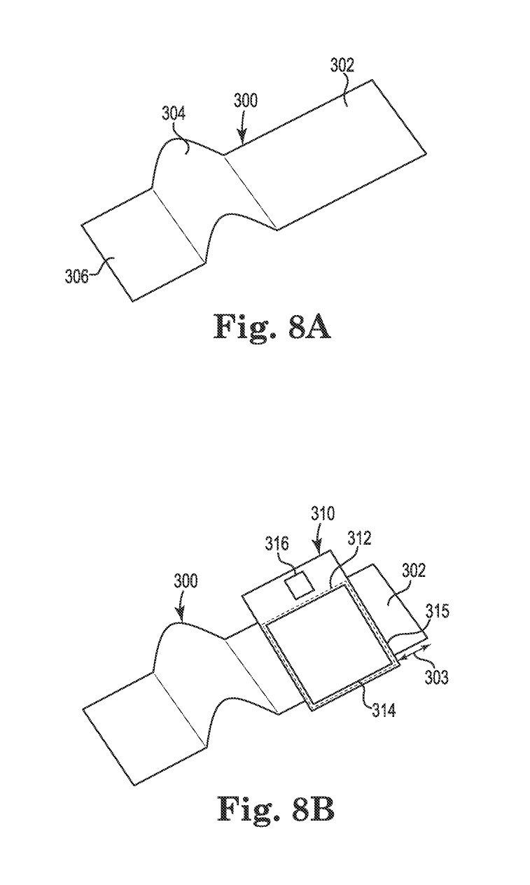

FIG. 6A illustrates a side view of one embodiment of a semiconductor device 200a coupled to a Printed Circuit Board (PCB) 202. Semiconductor device 200a is surface mounted onto a flat PCB 202. Semiconductor device 200a includes a mold material 204 encapsulating a semiconductor chip and portions of flexible leads 206a, 208a, and 210a. Flexible leads 206a, 208a, and 210a are flat and comprise an elastic or softening material. In one embodiment, flexible lead 206a is electrically coupled to a drain electrode, flexible lead 208a is electrically coupled to a source electrode, and flexible lead 210a is electrically coupled to a gate electrode of a MOSFET semiconductor chip encapsulated by mold compound 204. In another embodiment, flexible lead 206a is electrically coupled to a collector electrode, flexible lead 208a is electrically coupled to an emitter electrode, and flexible lead 210a is electrically coupled to a base electrode of an IGBT semiconductor chip encapsulated by mold compound 204.

FIG. 6B illustrates a side view of one embodiment of a semiconductor device 200b coupled to a PCB 202. Semiconductor device 200b is similar to semiconductor device 200a previously described and illustrated with reference to FIG. 6A, except that semiconductor device 200b includes flexible leads 206b, 208b, and 210b. Flexible leads 206b, 208b, and 210b are pre-formed and include a curved portion that in one embodiment gives flexible leads 206b, 208b, and 210b a spring-like characteristic. In other embodiments, flexible leads 206b, 208b, and 210b comprise an elastic or softening material.

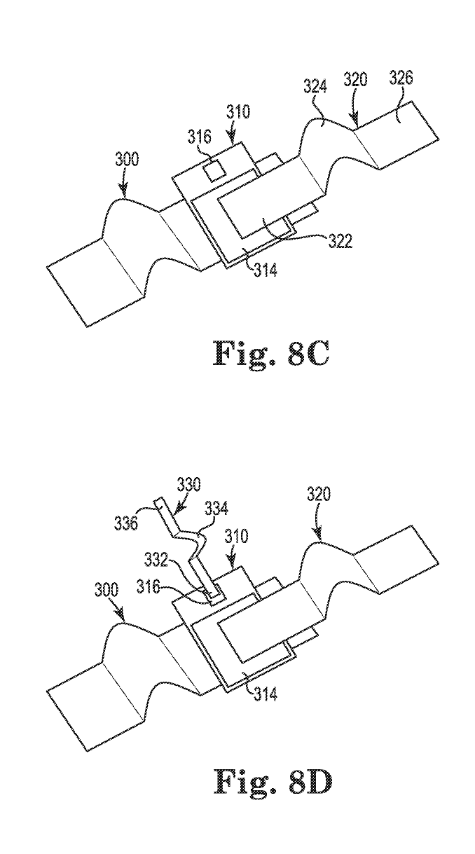

FIG. 7A illustrates a side view of one embodiment of semiconductor device 200a coupled to a flexible PCB 220. Flexible PCB 220 is curved and flexible leads 206a, 208a, and 210a and mold compound 204 flex to match the curvature of flexible PCB 220. Flexible leads 206a, 208a, and 210a and mold compound 204 flex without damaging flexible leads 206a, 208a, and 210a or mold compound 204.

FIG. 7B illustrates a side view of one embodiment of semiconductor device 200b coupled to a flexible PCB 220. In this embodiment, flexible leads 206b, 208b, and 210b and mold compound 204 flex to match the curvature of flexible PCB 220. Flexible leads 206b, 208b, and 210b and mold compound 204 flex without damaging flexible leads 206b, 208b, and 210b or mold compound 204.

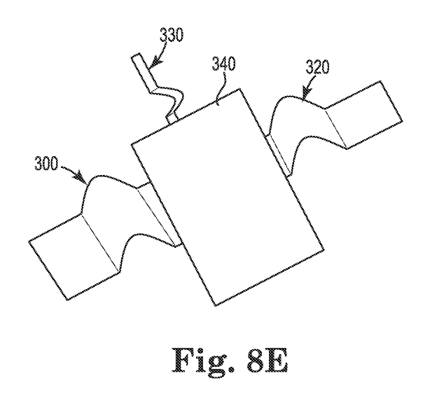

FIGS. 8A-8E illustrate one embodiment of a method for fabricating a semiconductor device. FIG. 8A illustrates a top view of one embodiment of a flexible ribbon lead 300 including a first portion 302, a second portion 304, and a third portion 306. First portion 302 is for electrically coupling lead 300 to a semiconductor chip. Second portion 304 is U-shaped and extends between the first portion 302 and the third portion 306. In one embodiment, second portion 304 gives flexible lead 300 a spring-like characteristic. Third portion 306 is for electrically coupling lead 300 to a PCB.

FIG. 8B illustrates a top view of one embodiment of a semiconductor chip 310 electrically coupled to flexible lead 300. Semiconductor chip 310 includes a first electrode 312 (indicated by dashed lines) on a bottom side of the semiconductor chip, and a second electrode 314 and a third electrode 316 on a top side of the semiconductor chip. In one embodiment, semiconductor chip 310 is a MOSFET semiconductor chip, and first electrode 312 is a drain electrode, second electrode 314 is a source electrode, and third electrode 316 is a gate electrode. In another embodiment, semiconductor chip 310 is an IGBT semiconductor chip, and first electrode 312 is a collector electrode, second electrode 314 is an emitter electrode, and third electrode 316 is a base electrode. First electrode 312 of semiconductor chip 310 is connected to first portion 302 of flexible lead 300 by soft soldering, diffusion soldering, sintering, or other suitable method to electrically couple first electrode 312 to flexible lead 300. In one embodiment, semiconductor chip 310 is connected to flexible lead 300 such that part of first portion 302 of flexible lead 300 extends past an edge 315 of semiconductor chip 310 by a distance indicated at 303.

FIG. 8C illustrates a top view of one embodiment of semiconductor chip 310 electrically coupled to flexible lead 300 and a flexible lead 320. Flexible lead 320 is a flexible ribbon lead including a first portion 322, a second portion 324, and a third portion 326. First portion 322 is for electrically coupling lead 300 to a semiconductor chip. Second portion 324 is U-shaped and extends between the first portion 322 and the third portion 326. In one embodiment, second portion 324 gives flexible lead 320 a spring-like characteristic. Third portion 326 is for electrically coupling lead 320 to a PCB. Second electrode 314 of semiconductor chip 310 is connected to first portion 322 of flexible lead 320 by soft soldering, diffusion soldering, sintering, or other suitable method to electrically couple second electrode 314 to flexible lead 320.

FIG. 8D illustrates a top view of one embodiment of semiconductor chip 310 electrically coupled to flexible lead 300, flexible lead 320, and a flexible lead 330. Flexible lead 330 is a flexible ribbon lead including a first portion 332, a second portion 334, and a third portion 336. First portion 332 is for electrically coupling lead 330 to a semiconductor chip. Second portion 334 is U-shaped and extends between the first portion 332 and the third portion 336. In one embodiment, second portion 334 gives flexible lead 330 a spring-like characteristic. Third portion 336 is for electrically coupling lead 330 to a PCB. Third electrode 316 of semiconductor chip 310 is connected to first portion 332 of flexible lead 330 by soft soldering, diffusion soldering, sintering, or other suitable method to electrically couple third electrode 316 to flexible lead 330.

FIG. 8E is a top view illustrating one embodiment of a mold compound 340 encapsulating semiconductor chip 310 and portions of flexible leads 300, 320, and 330. A hard or soft mold compound 340 is applied to semiconductor chip 310 and first portions 302, 322, and 332 of flexible leads 300, 320, and 330, respectively, by an injection molding process or another suitable process. The semiconductor device may then be surface mounted onto a flat PCB as previously described and illustrated with reference to FIGS. 6A and 6B or surface mounted onto a flexible PCB that may be flexed such that the PCB is curved as previously described and illustrated with reference to FIGS. 7A and 7B.

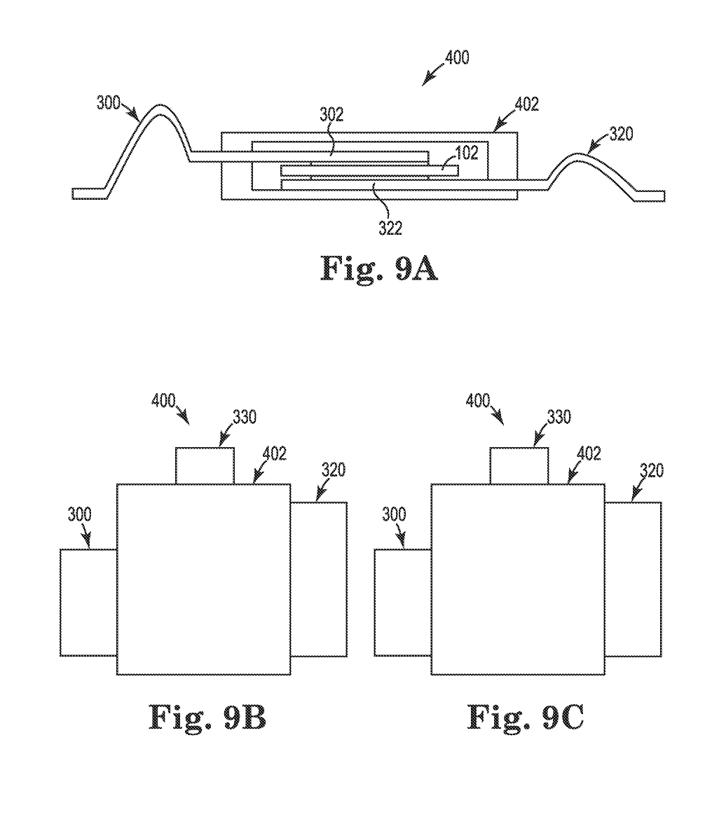

FIG. 9A illustrates a cross-sectional view, FIG. 9B illustrates a top view, and FIG. 9C illustrates a bottom view of one embodiment of a mold compound arrangement for a semiconductor device 400. Semiconductor device 400 includes a semiconductor chip 102, flexible leads 300, 320, and 330, and a mold compound 402. In this embodiment, mold compound 402 encapsulates semiconductor chip 102, first portion 302 of flexible lead 300, first portion 322 of flexible lead 320, and first portion 332 (FIG. 8D) of flexible lead 330.

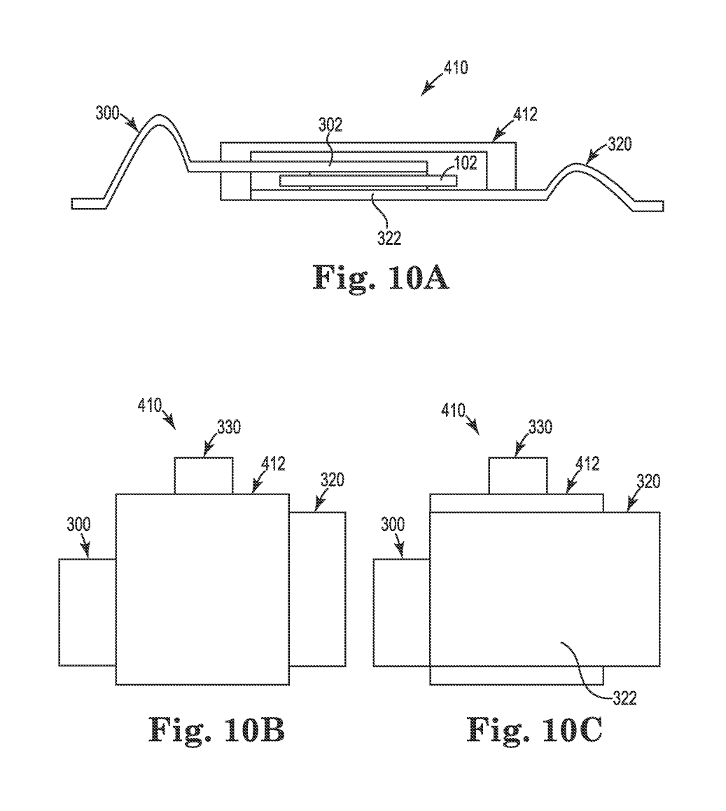

FIG. 10A illustrates a cross-sectional view, FIG. 10B illustrates a top view, and FIG. 10C illustrates a bottom view of one embodiment of a mold compound arrangement for a semiconductor device 410. Semiconductor device 410 includes a semiconductor chip 102, flexible leads 300, 320, and 330, and a mold compound 412. In this embodiment, mold compound 412 encapsulates semiconductor chip 102, first portion 302 of flexible lead 300, and first portion 332 (FIG. 8D) of flexible lead 330. First portion 322 of flexible lead 320 remains exposed.

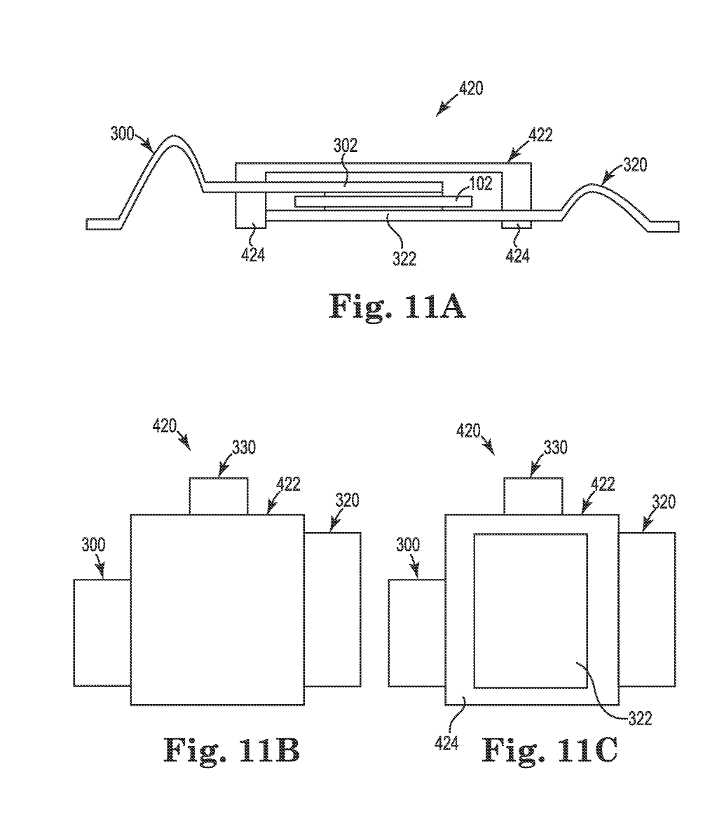

FIG. 11A illustrates a cross-sectional view, FIG. 11B illustrates a top view, and FIG. 11 C illustrates a bottom view of one embodiment of a mold compound arrangement for a semiconductor device 420. Semiconductor device 420 includes a semiconductor chip 102, flexible leads 300, 320, and 330, and a mold compound 422. In this embodiment, mold compound 422 encapsulates semiconductor chip 102, first portion 302 of flexible lead 300, and first portion 332 (FIG. 8D) of flexible lead 330. First portion 322 of flexible lead 320 remains exposed except for a spacer portion 424 of mold compound 422. In one embodiment, when mounted on a PCB, spacer portion 424 defines an air gap or an area for placing a micro heat sink or micro pipes between the PCB and first portion 322 of flexible lead 320.

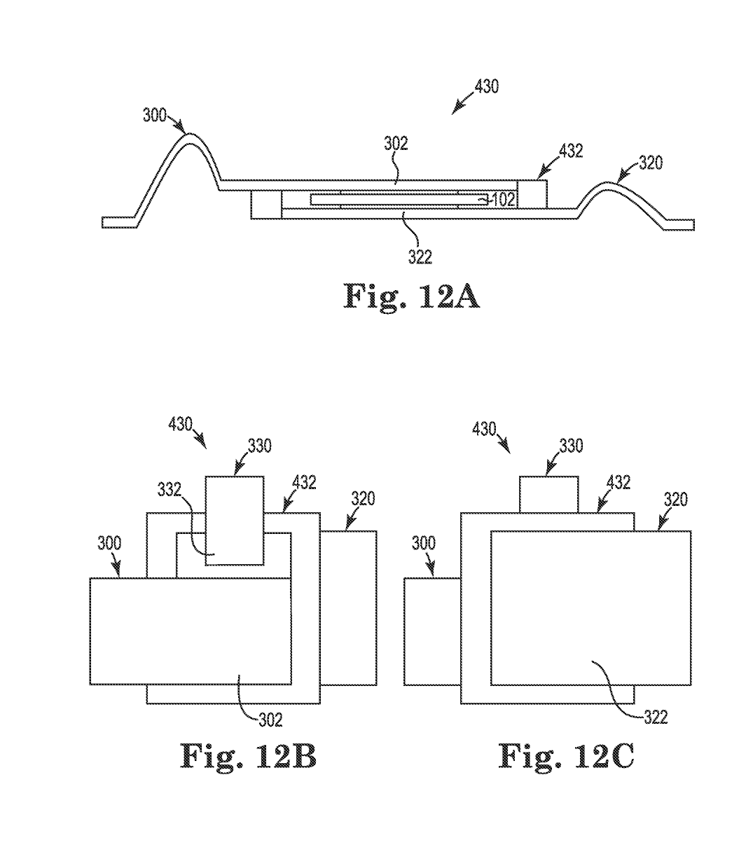

FIG. 12A illustrates a cross-sectional view, FIG. 12B illustrates a top view, and FIG. 12C illustrates a bottom view of one embodiment of a mold compound arrangement for a semiconductor device 430. Semiconductor device 430 includes a semiconductor chip 102, flexible leads 300, 320, and 330, and a mold compound 432. In this embodiment, mold compound 432 encapsulates semiconductor chip 102. First portion 302 of flexible lead 300, first portion 332 of flexible lead 330, and first portion 322 of flexible lead 320 remain exposed.

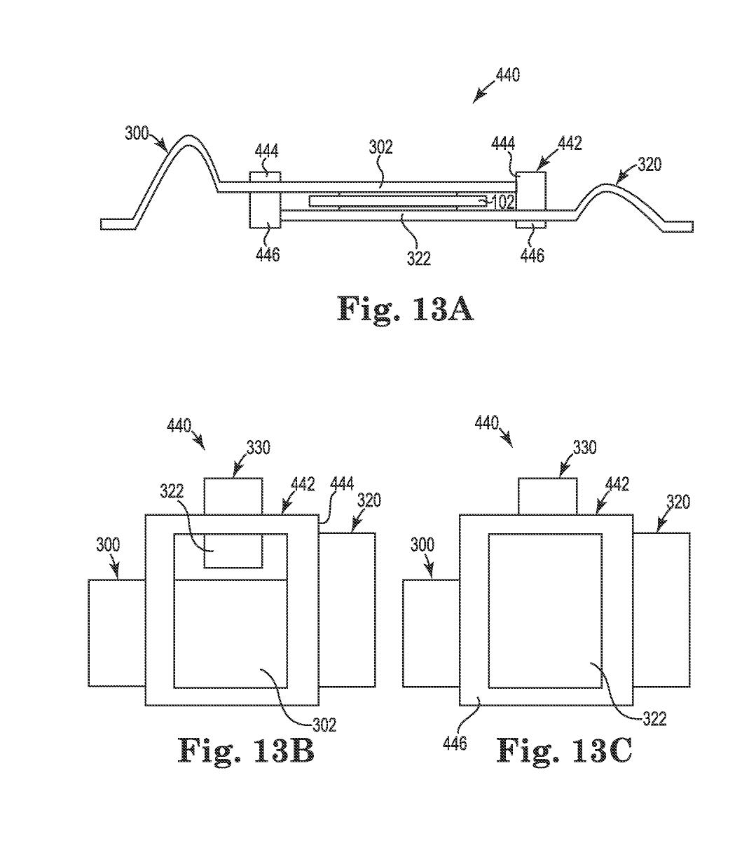

FIG. 13A illustrates a cross-sectional view, FIG. 13B illustrates a top view, and FIG. 13C illustrates a bottom view of one embodiment of a mold compound arrangement for a semiconductor device 440. Semiconductor device 440 includes a semiconductor chip 102, flexible leads 300, 320, and 330, and a mold compound 442. In this embodiment, mold compound 442 encapsulates semiconductor chip 102. First portion 302 of flexible lead 300 remains exposed except for a spacer portion 444 of mold compound 442. First portion 332 of flexible lead 330 also remains exposed except for spacer portion 444 of mold compound 442. First portion 322 of flexible lead 320 remains exposed except for a spacer portion 446 of mold compound 442. In one embodiment, when mounted on a PCB, spacer portion 446 defines an air gap or an area for placing a micro heat sink or micro pipes between the PCB and first portion 322 of flexible lead 320.

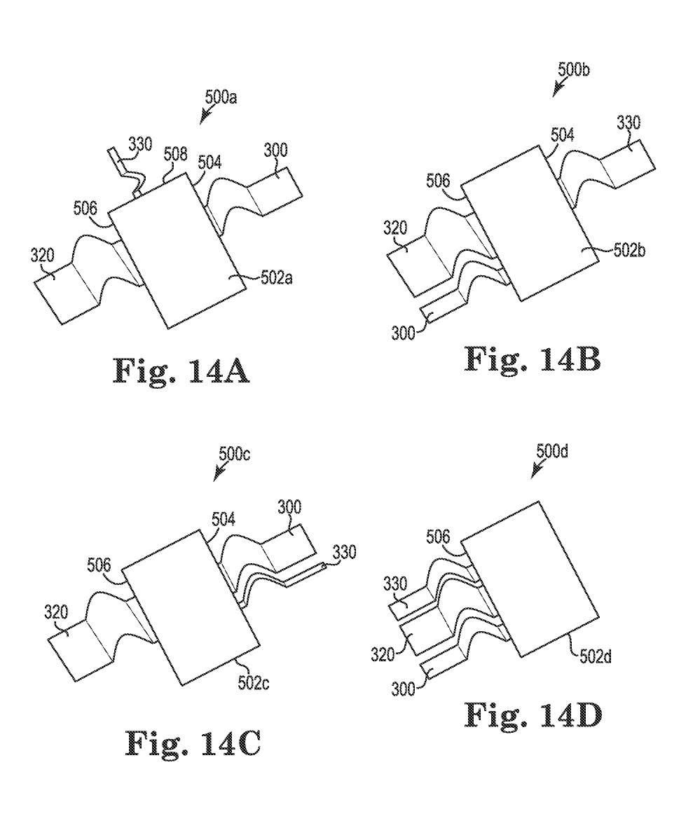

FIG. 14A illustrates one embodiment of a flexible lead arrangement for a semiconductor device 500a. Semiconductor device 500a includes flexible leads 300, 320, and 330 and a mold compound 502a encapsulating a semiconductor chip. In one embodiment, the semiconductor chip encapsulated by mold compound 502a is a MOSFET semiconductor chip, and flexible lead 300 is electrically coupled to a drain electrode, flexible lead 320 is electrically coupled to a source electrode, and flexible lead 330 is electrically coupled to a gate electrode of the semiconductor chip. In another embodiment, the semiconductor chip encapsulated by mold compound 502a is an IGBT semiconductor chip, and flexible lead 300 is electrically coupled to a collector electrode, flexible lead 320 is electrically coupled to an emitter electrode, and flexible lead 330 is electrically coupled to a base electrode of the semiconductor chip.

In this embodiment, flexible lead 300 extends from a first side 504 of the semiconductor chip, flexible lead 320 extends from a second side 506 of the semiconductor chip, and flexible lead 330 extends from a third side 508 of the semiconductor chip. First side 504 is opposite to second side 506, and third side 508 extends between first side 504 and second side 506.

FIG. 14B illustrates one embodiment of a flexible lead arrangement for a semiconductor device 500b. Semiconductor device 500b includes flexible leads 300, 320, and 330 and a mold compound 502b encapsulating a semiconductor chip. In this embodiment, flexible lead 330 extends from first side 504 of the semiconductor chip, and flexible leads 300 and 320 extend from second side 506 of the semiconductor chip.

FIG. 14C illustrates one embodiment of a flexible lead arrangement for a semiconductor device 500c. Semiconductor device 500c includes flexible leads 300, 320, and 330 and a mold compound 502c encapsulating a semiconductor chip. In this embodiment, flexible leads 300 and 330 extend from first side 504 of the semiconductor chip, and flexible lead 320 extends from second side 506 of the semiconductor chip.

FIG. 14D illustrates one embodiment of a flexible lead arrangement for a semiconductor device 500d. Semiconductor device 500d includes flexible leads 300, 320, and 330 and a mold compound 502d encapsulating a semiconductor chip. In this embodiment, flexible leads 300, 320, and 330 extend from the same side 506 of the semiconductor chip. Flexible lead 320 is arranged between flexible lead 330 and flexible lead 300.

While FIGS. 14A-14D illustrate several embodiments for the arrangement of the flexible leads of a semiconductor device, in other embodiments the flexible leads may have other suitable arrangements.

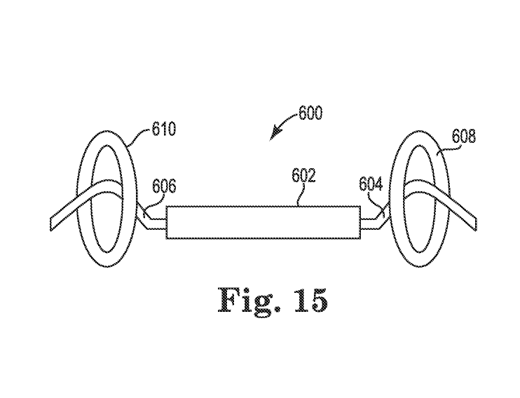

FIG. 15 illustrates a side view of one embodiment of a semiconductor device 600 including ferrite coils around the flexible leads. Semiconductor device 600 includes flexible leads 604 and 606 and a mold material 602 encapsulating a semiconductor chip. A first ferrite coil 608 is arranged around flexible lead 604, and a second ferrite coil 610 is arranged around flexible lead 606. The diameter of the ferrite coils 608 and 610 may be between about 1 mm and 24 mm. In one embodiment, ferrite coils 608 and 610 reduce noise on signals transmitted through flexible leads 604 and 606, respectively.

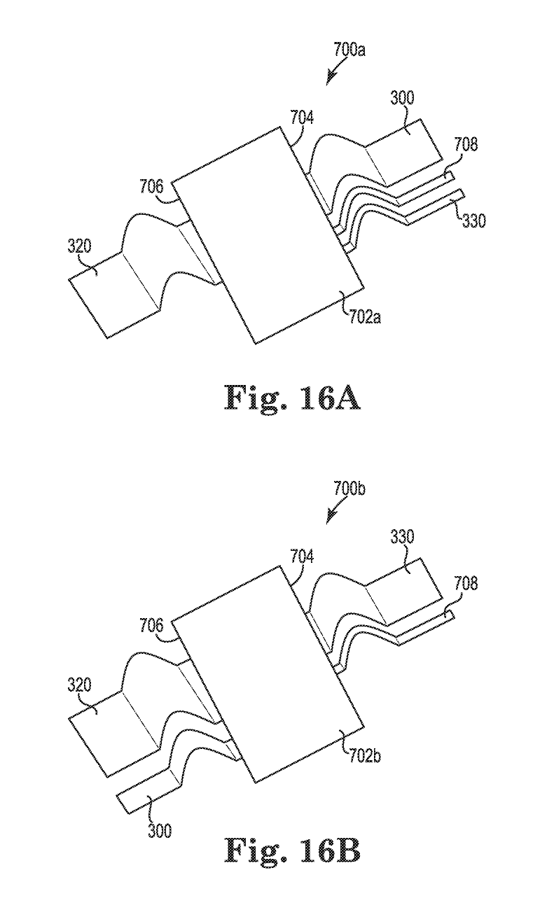

FIG. 16A illustrates one embodiment of a flexible lead arrangement for a semiconductor device 700a including an additional, or fourth flexible lead. In one example, the additional flexible lead is a source sense flexible lead 708. Semiconductor device 700a includes flexible leads 300, 320, 330, and 708 and a mold compound 702a encapsulating a semiconductor chip. In one embodiment, the semiconductor chip encapsulated by mold compound 702a is a MOSFET semiconductor chip, and flexible lead 320 is electrically coupled to a drain electrode, flexible lead 300 is electrically coupled to a source electrode, flexible lead 330 is electrically coupled to a gate electrode, and flexible lead 708 is electrically coupled to a source sense electrode of the semiconductor chip.

In this embodiment, flexible leads 300, 330, and 708 extend from a first side 704 of the semiconductor chip, and flexible lead 320 extends from a second side 706 of the semiconductor chip. First side 704 of the semiconductor chip is opposite to second side 706.

FIG. 16B illustrates another embodiment of a flexible lead arrangement for a semiconductor device 700b including a source sense flexible lead 708. Semiconductor device 700b includes flexible leads 300, 320, 330, and 708 and a mold compound 702b encapsulating a semiconductor chip. In this embodiment, flexible leads 330 and 708 extend from first side 704 of the semiconductor chip, and flexible leads 300 and 320 extend from second side 706 of the semiconductor chip.

While FIGS. 16A-16B illustrate two embodiments for the arrangement of the flexible leads of a semiconductor device, in other embodiments the flexible leads may have other suitable arrangements.

Embodiments of the disclosure provide semiconductor devices including flexible leads. The flexible leads enable the semiconductor devices to be mounted on flexible PCBs that may be curved without damaging the semiconductor devices. Further embodiments of the disclosure provide semiconductor devices including a flexible mold compound in addition to the flexible leads. The flexible leads and/or the flexible mold compound enable the semiconductor devices to be used in a wide variety of applications, such as portable electronic devices (e.g., mobile phones) having different shapes and sizes.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A semiconductor device comprising:
a semiconductor chip comprising a transistor;
a first flexible lead electrically coupled to a first electrode on a first surface of the semiconductor chip, a portion of the first flexible lead aligned with the first electrode in a direction perpendicular to the semiconductor chip;
a second flexible lead electrically coupled to a second electrode on the first surface of the semiconductor chip, a portion of the second flexible lead aligned with the second electrode in the direction perpendicular to the semiconductor chip; and
a third flexible lead electrically coupled to a third electrode on a second surface of the semiconductor chip, the second surface opposite to the first surface, a portion of the third flexible lead aligned with the third electrode in the direction perpendicular to the semiconductor chip.

2. The semiconductor device of claim 1, wherein each of the first flexible lead, the second flexible lead, and the third flexible lead comprises a pre-formed ribbon lead having a spring-like characteristic.

3. The semiconductor device of claim 1, wherein each of the first flexible lead, the second flexible lead, and the third flexible lead comprises an elastic or softening material.

4. The semiconductor device of claim 1, wherein each of the first flexible lead, the second flexible lead, and the third flexible lead comprises a solder material.

5. The semiconductor device of claim 1, wherein the transistor is a metal-oxide-semiconductor field-effect transistor,
wherein the first electrode comprises a gate electrode of the transistor,
wherein the second electrode comprises a source electrode of the transistor, and
wherein the third electrode comprises a drain electrode of the transistor.

6. The semiconductor device of claim 5, wherein the first flexible lead has a first width,
wherein the second flexible lead has a second width greater than the first width, and
wherein the third flexible lead has a third width greater than the first width.

7. The semiconductor device of claim 1, wherein the transistor is an insulated gate bipolar transistor,
wherein the first electrode comprises a base electrode of the transistor,
wherein the second electrode comprises a collector electrode of the transistor, and
wherein the third electrode comprises an emitter electrode of the transistor.

8. The semiconductor device of claim 7, wherein the first flexible lead has a first width,
wherein the second flexible lead has a second width greater than the first width, and
wherein the third flexible lead has a third width greater than the first width.

9. A semiconductor device comprising:
a semiconductor chip comprising a transistor, the semiconductor chip having a first surface and a second surface opposite to the first surface;
a first flexible lead electrically coupled to the first surface, a portion of the first flexible lead aligned with the semiconductor chip in a direction perpendicular to the semiconductor chip;
a second flexible lead electrically coupled to the second surface, a portion of the second flexible lead aligned with the semiconductor chip in the direction perpendicular to the semiconductor chip; and
a mold compound encapsulating the semiconductor chip.

10. The semiconductor device of claim 9, wherein the mold compound comprises a soft or elastic mold compound.

11. The semiconductor device of claim 9, wherein the mold compound encapsulates a portion of the first flexible lead.

12. The semiconductor device of claim 11, wherein the mold compound encapsulates a portion of the second flexible lead.

13. The semiconductor device of claim 11, wherein the mold compound encapsulates the semiconductor chip and the portion of the first flexible lead such that the second flexible lead is exposed.

14. The semiconductor device of claim 9, wherein the mold compound comprises a spacer on a portion of the first flexible lead such that with the semiconductor device mounted on a printed circuit board, the spacer defines an air gap between the printed circuit board and the first flexible lead.

15. The semiconductor device of claim 9, further comprising:
a ferrite coil around the first flexible lead.

16. A method for fabricating a semiconductor device, the method comprising:
electrically coupling a first electrode on a first surface of a semiconductor chip to a first flexible lead such that a portion of the first flexible lead is aligned with the first electrode in a direction perpendicular to the semiconductor chip, the semiconductor chip comprising a transistor;
electrically coupling a second flexible lead to a second electrode on a second surface of the semiconductor chip such that a portion of the second flexible lead is aligned with the second electrode in the direction perpendicular to the semiconductor chip, the second surface opposite to the first surface; and
electrically coupling a third flexible lead to a third electrode on the second surface of the semiconductor chip such that a portion of the third flexible lead is aligned with the third electrode in the direction perpendicular to the semiconductor chip.

17. The method of claim 16, further comprising:
encapsulating the semiconductor chip and at least a portion of the first flexible lead, the second flexible lead, and the third flexible lead with a mold compound.

18. The method of claim 17, wherein the mold compound comprises a soft or elastic mold compound.

19. The method of claim 16, further comprising:
electrically coupling the first flexible lead, the second flexible lead, and the third flexible lead to a flexible printed circuit board.

20. The method of claim 19, further comprising:
flexing the printed circuit board such that the printed circuit board is curved.
